(19) United States
(12) Patent Application Publication
(10) Pub. No.: US 2024/0368752 A1
(43) Pub. Date: Nov. 7, 2024

(54) DYNAMIC SEAL SYSTEM FOR A VACUUM PROCESSING SYSTEM

(71) Applicant: Plasma-Therm NES LLC, St. Petersburg, FL (US)

(72) Inventors: Sarpangala Hariharakeshava Hegde, Fremont, CA (US); Vincent C. Lee, Fremont, CA (US); Wei-Hua Hsiao, St. Petersburg, FL (US); Jerome Michael Buckley, St. Petersburg, FL (US)

(73) Assignee: Plasma-Therm NES LLC, St. Petersburg, FL (US)

(21) Appl. No.: 18/141,921

(22) Filed: May 1, 2023

(51) Int. Cl. C23C 14/56; C23C 14/22; C23C 14/50

(52) U.S. Cl. CPC C23C 14/564; C23C 14/221; C23C 14/505

(57) ABSTRACT

The present disclosure provides an improved dynamic seal system for a vacuum processing system that has a vacuum chamber within a process module. A rotational wafer stage is positioned within the process module. A first fluid line is operatively connected to the rotational wafer stage. A first differential pump line is operatively connected to the rotational wafer stage. A dynamic seal surrounds the first fluid line and the first differential pump line. The differential pumping of the dynamic seal by the first differential pump line, drains the first fluid from the dynamic seal to outside the tilt housing allowing for the monitoring of the dynamic seal for the presence of the first fluid outside the process module.

### TECHNICAL FIELD

The present disclosure relates to the field of charged particle sources including plasma sources for direct etching and deposition, broad-beam ion sources for ion beam deposition and etching, and electron sources for surface modification.

### BACKGROUND

Dynamic seals are used as a pressure breakdown means as well as to alleviate or resolve pump sealing problems. Dynamic seals can substantially reduce maintenance costs, but leakage costs can be a concern inside a chamber of a vacuum process system. Dynamic seals are used between at least one moving or rotating valve part and another part that may be moving or nonmoving. Dynamic seals can be more critical, since they are at higher risk of wearing and tearing due to friction with one or two moving parts.

As shown in FIG. 1, a typical vacuum chamber 20 of an ion beam system 10, has a ferrofluidic rotational vacuum seal 30 for a rotatable wafer stage 40 that rotates on one axis. In an atmospheric part of the vacuum chamber 20, a dynamic seal(s) 50 surrounds a first fluid line in, a first fluid line out, a second fluid line in and a second fluid line out to the wafer stage. The first fluid can be a liquid such as water and the second fluid can be a cooling gas such as helium. Typically, there is a water sensor 60 within the atmospheric part of the vacuum chamber 20 to detect leaking water from the first fluid line. The helium in the second fluid line provides backside cooling to the wafer, by draining the thermal load from the wafer to the water cooled wafer stage.

Due to the need to provide wafer rotational capability on a wafer stage that tilts inside the vacuum system 10, when the dynamic seal(s) 50 for the first fluid line fail, water can infiltrate the inside the atmospheric part of the vacuum system 20 and damage sensitive components like motors, encoders, and sensors.

Water sensing electronic modules can alert the user about impending failure of dynamic seal(s) 50. However, water sensor(s) 60 need to be installed inside the wafer stage fixture which in turn is mounted inside the vacuum system 10. Maintenance of the water sensor 60 and/or replacing an erratic water sensor 60, (e.g., false positive reading for the presence of water) requires the vacuum system 10 to be vented and the vacuum chamber 20 to be opened. Due to the cumbersome nature of the maintenance of the water sensor 60, users tend to disable the water sensor 60. Thus, worsening any damage that occurs due to water leakage from the first fluid line.

When the dynamic seal for the second fluid line starts leaking helium, as the wafer is unclamped, atmospheric air can leak into the process module, and cause wafer processes to drift and change. In high vacuum systems that require 10-6 Torr or better vacuum, even small atmospheric air leaks, or a water leak into the helium line from the dynamic seal surrounding the second fluid line can cause base pressure of the process chamber to be poor, and cause wafer process performance deterioration. Generally, when the vacuum chamber is vented and the wafer stage fixture is opened to service the wafer stage components inside the fixture, system availability is compromised, since the vacuum system 10 will need to be pumped down to high vacuum and process performance needs to be retested.

In prior art designs of helium and water dynamic seals, there is no way of monitoring the health and lifetime of rotational dynamic seals. Users generally go through maintenance of the dynamic seals based on use and/or based on a set time period, to prevent water leaks and/or atmospheric air leaks into the helium line which causes base vacuum of process chamber to deteriorate and process performance to degrade. This generally results in poor mean time between maintenance since users are forced to run maintenance on a shorter time frame to avoid water line and/or helium line leaks from the dynamic seal(s).

Prior art implementations of dynamic seal(s) surrounding fluid lines of water and/or helium show low mean time between maintenance, and poor reliability, and do not provide advanced diagnostics.

### SUMMARY OF THE INVENTION

The present invention provides an improved dynamic seal designed for high reliability, improved Mean Time Between Maintenance, ease of access for maintenance, and advanced diagnostics, in high vacuum wafer process systems that require wafer backside cooling with helium, wafer tilting and rotation of the wafer stage.

According to one aspect of an embodiment of the present disclosure, an improved dynamic seal system for a vacuum processing system comprising: a vacuum chamber within a process module; a rotational wafer stage within the process module; a first fluid line operatively connected to the rotational wafer stage; a first differential pump line operatively connected to the rotational wafer stage; and a dynamic seal surrounding the first fluid line and the first differential pump line.)

According to another aspect of an embodiment of the present disclosure, an improved dynamic seal system for a vacuum processing system comprising: a vacuum chamber within a process module; a rotational wafer stage within the process module; a first fluid line in operatively connected to the rotational wafer stage; a first fluid line out operatively connected to the rotational wafer stage; a second fluid line in operatively connected to the rotational wafer stage; a second fluid line out operatively connected to the rotational wafer stage; a first differential pump line operatively connected to the rotational wafer stage and operatively connected to the first fluid line in and the first fluid line out; a second differential pump line operatively connected to the rotational wafer stage and operatively connected to the second fluid line in and the second fluid line out; and a dynamic seal surrounding the first fluid line in, the first fluid line out, the second fluid line in, the second fluid line out, the first differential pump line, and the second differential pump line.

According to another aspect of an embodiment of the present disclosure, a method for an improved dynamic seal system for a vacuum processing system comprising the steps of: providing a vacuum chamber within a process module; providing a rotational wafer stage within the vacuum chamber; injecting a first fluid through a first fluid line to the rotational wafer stage, the first fluid line is covered by a dynamic seal at a first connection point to the rotational wafer stage; monitoring for a presence of the first fluid within the dynamic seal using a first leak sensor; and differentially pumping the presence of the first fluid from the dynamic seal through a first differential pump line based on the monitoring step of the presence of the first fluid.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims, or can be learned by the practice of the principles set forth herein.

### BRIEF DESCRIPTION OF THE DRAWINGS

In order to describe the manner in which the above-recited and other advantages and features of the disclosure can be obtained, a more particular description of the principles briefly described above will be rendered by reference to specific embodiments thereof which are illustrated in the appended drawings. Understanding that these drawings depict only exemplary embodiments of the disclosure and are not therefore to be considered to be limiting of its scope, the principles herein are described and explained with additional specificity and detail through the use of the accompanying drawings in which:

FIG. 1 is a schematic view of a typical prior art vacuum chamber;

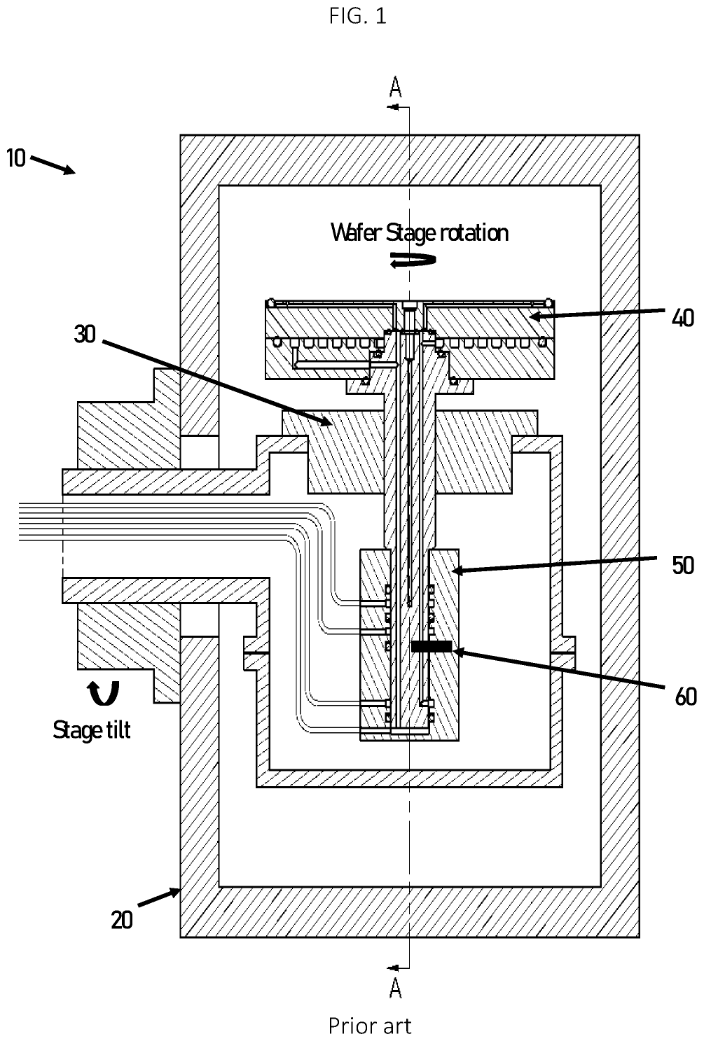

FIG. 2 is a schematic view of a vacuum chamber showing one embodiment of the present invention;

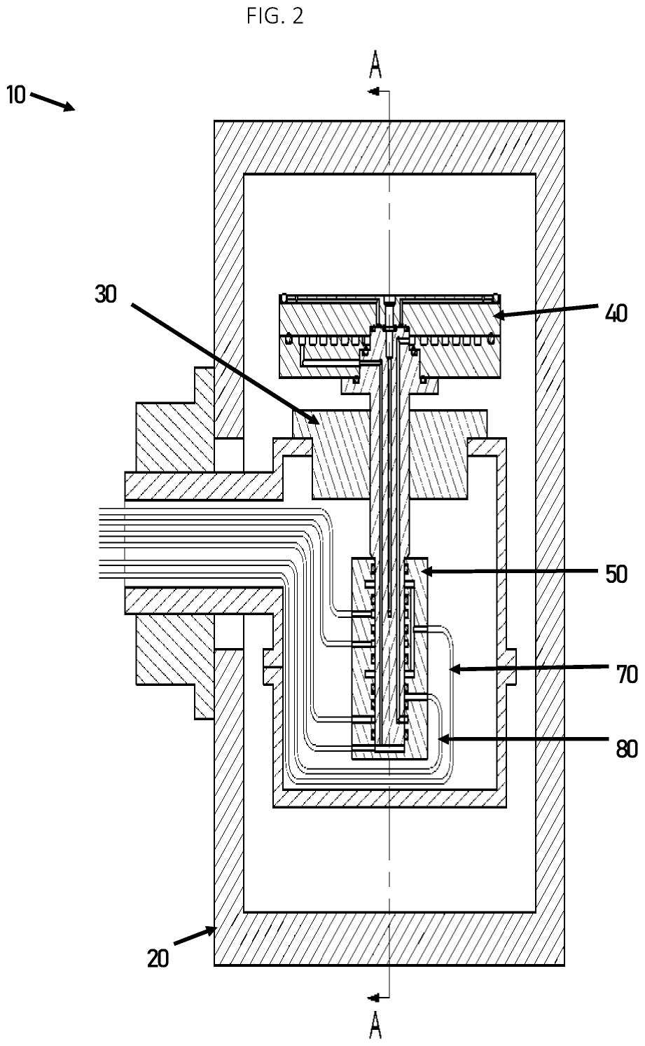

FIG. 3 is a blown up view of a dynamic seal surrounding a first differential pump line and a second differential pump line showing one embodiment of the present invention; and

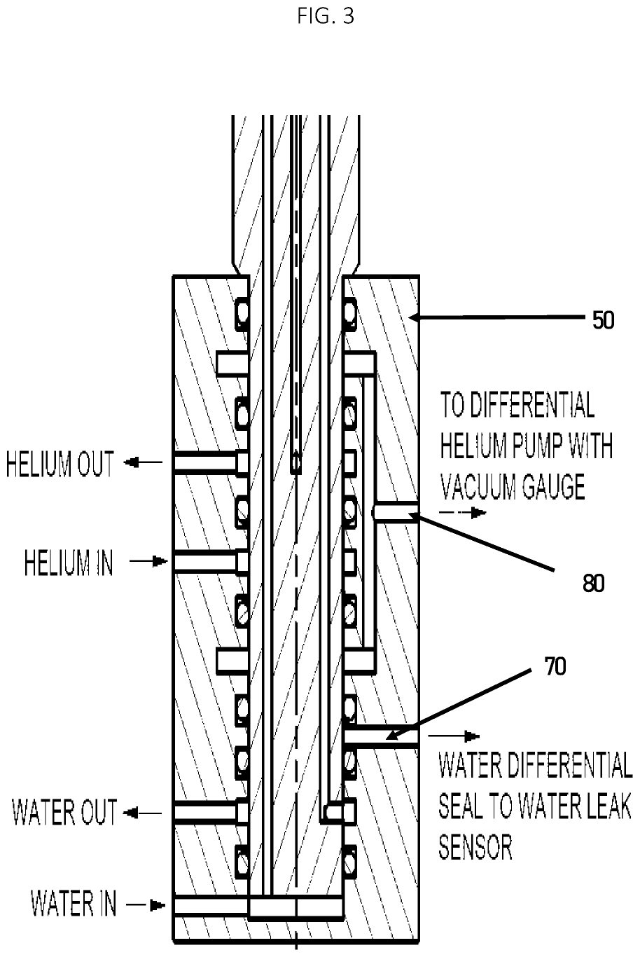

FIG. 4 is a schematic view of a vacuum chamber showing one embodiment of the present invention.

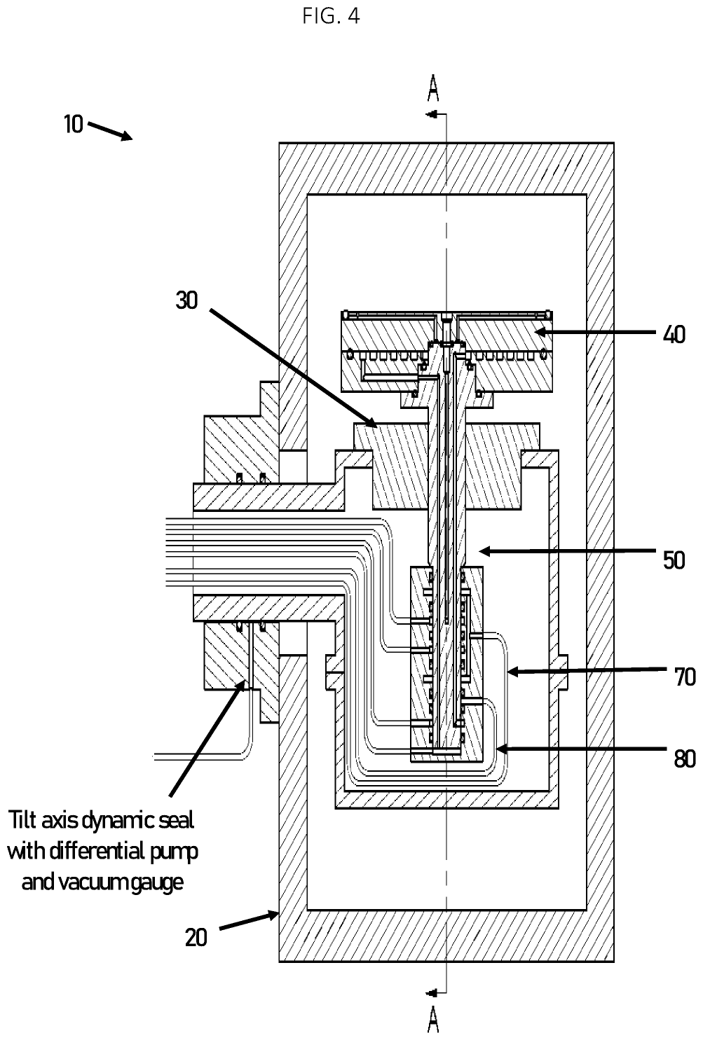

Similar reference characters refer to similar parts throughout the several views of the drawings.

### DETAILED DESCRIPTION

In one embodiment of the present invention, an improved dynamic seal system for a vacuum processing system 10 has a vacuum chamber within a process module. A rotational wafer stage 40 that can tilt on a motion axis is positioned within the process module. A first fluid line is operatively connected to the rotational wafer stage 40. The first fluid line can carry a liquid such as water. A first differential pump line 70 is operatively connected to the rotational wafer stage 40. A dynamic seal 50 surrounds the first fluid line and the first differential pump line 70. The dynamic seal 50 can be one or more dynamic seals 50. The first differential pump line 70 can pump leaked first fluid within the dynamic seal 50 from the first fluid line. There can be a first leak sensor that is operatively connected to the first differential pump line 70 that detects the leaked first fluid within the dynamic seal 50 from the first fluid line. The differential pumping of the dynamic seal 50 by the first differential pump line 70, drains the first fluid (e.g., water) from the dynamic seal 50 to outside the tilt housing allowing for the monitoring of the dynamic seal 50 for the presence of the first fluid which is also drained and can also provide an alert for maintenance of the dynamic seal 50. In addition, differential pumping of the dynamic seal 50 using the first differential pump line 70 while monitoring a pressure in the differential line of fluid with a vacuum gauge can provide a rate of dynamic seal 50 deterioration with prediction of the lifetime of the dynamic seal 50. The first leak sensor can be mounted outside the process module which allows for easy access and replacement of the first leak sensor. A drain can be operatively connected to the first differential pump line 70 wherein the drain is mounted outside the process module for easy access and maintenance. A second fluid line can be operatively connected to the rotational wafer stage 40 wherein at least one dynamic seal 50 surrounds the second fluid line. The second fluid line can carry a gas such as helium. The second differential pump line 80 can pump leaked second fluid within the dynamic seal 50 from the second fluid line. A second leak sensor can be operatively connected to the second differential pump line 80 that detects the leaked second fluid within the dynamic seal 50 from the second fluid line. The second leak sensor can be mounted outside the process module which allows for easy access and replacement of the second leak sensor. A vacuum gauge can be operatively connected to the second differential pump line 80 wherein the vacuum gauge is mounted outside the process module for easy access and maintenance. The differential pumping of the dynamic seal 50 by the second differential pump line 80, drains the second fluid (e.g., helium) from the dynamic seal 50 to outside the tilt housing allowing for the monitoring of the dynamic seal 50 for the presence of the second fluid which is also drained and can also provide an alert for maintenance of the dynamic seal 50. In addition, differential pumping of the dynamic seal 50 by the second differential pump line 80 while monitoring pressure in differential line of the second fluid dynamic seal 50 with the vacuum gauge can provide a rate of dynamic seal deterioration with prediction of the lifetime of the dynamic seal 50.)

In another embodiment of the present invention, an improved dynamic seal system for a vacuum processing system 10 has a vacuum chamber within a process module. A rotational wafer stage 40 that can tilt on a motion axis is positioned within the process module. A first fluid line in is operatively connected to the rotational wafer stage 40. A first fluid line out is operatively connected to the rotational wafer stage 40. The first fluid line can carry a liquid such as water. A second fluid line in is operatively connected to the rotational wafer stage 40. A second fluid line out is operatively connected to the rotational wafer stage 40. The second fluid line can carry a gas such as helium. A first differential pump line 70 is operatively connected to the rotational wafer stage 40 and the first differential pump line 70 is operatively connected to the first fluid line in and the first fluid line out. A second differential pump line 80 is operatively connected to the rotational wafer stage 40 and the second differential pump line 80 is operatively connected to the second fluid line in and the second fluid line out. A dynamic seal 50 surrounds the first fluid line in, the first fluid line out, the second fluid line in, the second fluid line out, the first differential pump line 70 and the second differential pump line 80. The dynamic seal 50 can be one or more dynamic seals 50. The first differential pump line 70 can pump leaked first fluid within the dynamic seal 50 from the first fluid line. The second differential pump line 80 can pump leaked second fluid within the dynamic seal 50 from the second fluid line. There can be a first leak sensor that is operatively connected to the first differential pump line 70 that detects the leaked first fluid within the dynamic seal 50 from the first fluid line. The differential pumping of the dynamic seal 50 by the first differential pump line 70, drains the first fluid (e.g., water) from the dynamic seal 50 to outside the tilt housing allowing for the monitoring of the dynamic seal 50 for the presence of the first fluid which is also drained and can also provide an alert for maintenance of the dynamic seal 50. In addition, differential pumping of the dynamic seal 50 by the first differential pump line 70 while monitoring pressure in the differential line of the first fluid seal with a vacuum gauge can provide a rate of dynamic seal deterioration with prediction of the lifetime of the dynamic seal 50. The first leak sensor can be mounted outside the process module which allows for easy access and replacement of the first leak sensor. A drain can be operatively connected to the first differential pump line 70 wherein the drain is mounted outside the process module for easy access and maintenance. A second leak sensor can be operatively connected to the second differential pump line 80 that detects the leaked second fluid within the dynamic seal 50 from the second fluid line. The second leak sensor can be mounted outside the process module which allows for easy access and replacement of the second leak sensor. A vacuum gauge can be operatively connected to the second differential pump line 80 wherein the vacuum gauge is mounted outside the process module for easy access and maintenance. The differential pumping of the dynamic seal 50 by the second differential pump line 80, drains the second fluid (e.g., helium) from the dynamic seal 50 to outside the tilt housing allowing for the monitoring of the differential seal 50 for the presence of the second fluid which is also drained and can also provide an alert for maintenance of the dynamic seal 50. In addition, differential pumping of the dynamic seal 50 by the second differential pump line 80 while monitoring pressure in differential line of second fluid seal with the vacuum gauge can provide a rate of dynamic seal deterioration with prediction of the lifetime of the dynamic seal 50.

In another embodiment of the present invention, a method for an improved dynamic seal system for a vacuum processing system 10 comprising the following steps. A vacuum chamber is provided within a process module. A rotational wafer stage 40 is provided that can tilt on a motion axis is positioned within the process module. A first fluid is injected through a first fluid line to the rotational wafer stage 40. The first fluid line is covered by a dynamic seal 50 at a first connection point to the rotational wafer stage 40. The first fluid line can carry a liquid such as water. A second fluid can be injected through a second fluid line to the rotational wafer stage 40. The second fluid line can be covered by a dynamic seal 50 at a second connection point to the rotational wafer stage 40. The second fluid line can carry a gas such as helium. The presence of the first fluid is monitored within the dynamic seal 50 using a first leak sensor. The presence of the first fluid is differentially pumped from the dynamic seal 50 through a first differential pump line 70 based on the monitoring step of the presence of the first fluid. The differential pumping of the dynamic seal 50 by the first differential pump line 70, drains the first fluid (e.g., water) from the dynamic seal 50 to outside the tilt housing allowing for the monitoring of the dynamic seal 50 for the presence of the first fluid which is also drained and can also provide an alert for maintenance of the dynamic seal 50. In addition, differential pumping of the dynamic seal 50 by the first differential pump line 70 while monitoring pressure in the differential line of the first fluid seal with a vacuum gauge can provide a rate of dynamic seal deterioration with prediction of the lifetime of the dynamic seal 50. The first leak sensor can be mounted outside the process module which allows for easy access and replacement of the first leak sensor. A drain can be operatively connected to the first differential pump line 70 wherein the drain is mounted outside the process module for easy access and maintenance. The presence of the second fluid can be monitored within the dynamic seal 50 using a second leak sensor. The presence of the second fluid can be differentially pumped from the dynamic seal 50 through a second differential pump line 80 based on the monitoring step of the presence of the second fluid. The second leak sensor can be mounted outside the process module which allows for easy access and replacement of the second leak sensor. A vacuum gauge can be operatively connected to the second differential pump line 80 wherein the vacuum gauge is mounted outside the process module for easy access and maintenance. The differential pumping of the dynamic seal 50 by the second differential pump line 80, drains the second fluid (e.g., helium) from the dynamic seal 50 to outside the tilt housing allowing for the monitoring of the differential seal 50 for the presence of the second fluid which is also drained and can also provide an alert for maintenance of the dynamic seal 50. In addition, differential pumping of the dynamic seal 50 by the second differential pump line 80 while monitoring pressure in differential line of second fluid seal with the vacuum gauge can provide a rate of dynamic seal deterioration with prediction of the lifetime of the dynamic seal 50.

Diagnostics and warning system based on water differential pump line pressure, implemented in the following way. Check and determine normal operational pressure of the differential line with vacuum gauge attached to the line. Monitor for pressure rise, up to an order of magnitude larger than the normal operational pressure, determine the time from the last maintenance, and extrapolate time left for maintenance. Alternately, monitor for pressure rise, up to a pre-determined pressure value, determine the time from the last maintenance, and extrapolate time left for maintenance. System software will give out a warning for “maintenance due” and “time left for maintenance.” When the differential pressure reaches a value two orders of magnitude larger than the normal value, system software will intervene to shutoff water flow, and operator intervention for maintenance of dynamic seal will be demanded. Alternately, when the differential pressure reaches a pre-determined “highest permissible value”, system software will intervene to shutoff water flow, and demand operator intervention for maintenance of dynamic seal. Pre-determined “highest permissible value” may be input as a multiple of the normal operational value up to a multiple of two orders of magnitude.

Diagnostics and warning system based on Helium differential pump line pressure, implemented in the following way. Check and determine normal operational pressure of the differential line with vacuum gauge attached to the line. Monitor for pressure rise, up to an order of magnitude larger than the normal operational pressure, determine the time from the last maintenance, and extrapolate time left for maintenance. Alternately, monitor for pressure rise, up to a pre-determined pressure value, determine the time from the last maintenance, and extrapolate time left for maintenance. System software will give out a warning for “maintenance due” and “time left for maintenance.” When the differential pressure reaches a value two orders of magnitude larger than the normal value, system software will intervene to shutoff water flow, and operator intervention for maintenance of dynamic seal will be demanded. Alternately, when the differential pressure reaches a pre-determined “highest permissible value”, system software will intervene to shutoff water flow, and demand operator intervention for maintenance of dynamic seal. Pre-determined “highest permissible value” may be input as a multiple of the normal operational value up to a multiple of two orders of magnitude.

Although a variety of examples and other information was used to explain aspects within the scope of the appended claims, no limitation of the claims should be implied based on particular features or arrangements in such examples, as one of ordinary skill would be able to use these examples to derive a wide variety of implementations. Further, and although some subject matter may have been described in language specific to examples of structural features and/or method steps, it is to be understood that the subject matter defined in the appended claims is not necessarily limited to these described features or acts. For example, such functionality can be distributed differently or performed in components other than those identified herein. Rather, the described features and steps are disclosed as examples of components of systems and methods within the scope of the appended claims. Moreover, claim language reciting “at least one of” a set indicates that one member of the set or multiple members of the set satisfy the claim.

What is claimed is:

1. An improved dynamic seal system for a vacuum processing system comprising:
a vacuum chamber within a process module;
a rotational wafer stage within the process module;
a first fluid line operatively connected to the rotational wafer stage;
a first differential pump line operatively connected to the rotational wafer stage; and
a dynamic seal surrounding the first fluid line and the first differential pump line.

2. The improved dynamic seal system according to claim 1 wherein the wafer stage is mounted on another motion axis.

3. The improved dynamic seal system according to claim 1 further comprising a first leak sensor operatively connected to the first differential pump line.

4. The improved dynamic seal system according to claim 3 wherein said first leak sensor is mounted outside the process module.

5. The improved dynamic seal system according to claim 4 further comprising a drain operatively connected to the first differential pump line, said drain is mounted outside the process module.

6. The improved dynamic seal system according to claim 1 further comprising a second fluid line operatively connected to the rotational wafer stage, the dynamic seal surrounding the second fluid line.

7. The improved dynamic seal system according to claim 6 further comprising a second differential pump line operatively connected to the rotational wafer stage, the dynamic seal surrounding the second differential pump line.

8. The improved dynamic seal system according to claim 7 further comprising a second leak sensor operatively connected to the second differential pump line.

9. The improved dynamic seal system according to claim 8 wherein said second leak sensor is mounted outside the process module.

10. The improved dynamic seal system according to claim 7 further comprising a vacuum gauge operatively connected to the second differential pump line, said vacuum gauge is mounted outside the process module.

11. An improved dynamic seal system for a vacuum processing system comprising:
a vacuum chamber within a process module;
a rotational wafer stage within the process module;
a first fluid line in operatively connected to the rotational wafer stage;
a first fluid line out operatively connected to the rotational wafer stage;
a second fluid line in operatively connected to the rotational wafer stage;
a second fluid line out operatively connected to the rotational wafer stage;
a first differential pump line operatively connected to the rotational wafer stage and operatively connected to the first fluid line in and the first fluid line out;
a second differential pump line operatively connected to the rotational wafer stage and operatively connected to the second fluid line in and the second fluid line out; and
a dynamic seal surrounding the first fluid line in, the first fluid line out, the second fluid line in, the second fluid line out, the first differential pump line, and the second differential pump line.

12. The improved dynamic seal system according to claim 11 wherein the wafer stage is mounted on another motion axis.

13. The improved dynamic seal system according to claim 11 further comprising a first leak sensor operatively connected to the first differential pump line.

14. The improved dynamic seal system according to claim 13 wherein said first leak sensor is mounted outside the process module.

15. The improved dynamic seal system according to claim 14 further comprising a second leak sensor operatively connected to the second differential pump line.

16. The improved dynamic seal system according to claim 15 wherein said second leak sensor is mounted outside the process module.

17. The improved dynamic seal system according to claim 11 further comprising a drain operatively connected to the first differential pump line, said drain is mounted outside the process module.

18. The improved dynamic seal system according to claim 11 further comprising a vacuum gauge operatively connected to the second differential pump line, said vacuum gauge is mounted outside the process module.

19. A method for an improved dynamic seal system for a vacuum processing system comprising the steps of:
providing a vacuum chamber within a process module;
providing a rotational wafer stage within the vacuum chamber;
injecting a first fluid through a first fluid line to the rotational wafer stage, the first fluid line is covered by a dynamic seal at a first connection point to the rotational wafer stage;
monitoring for a presence of the first fluid within the dynamic seal using a first leak sensor; and
differentially pumping the presence of the first fluid from the dynamic seal through a first differential pump line based on the monitoring step of the presence of the first fluid.

20. The method according to claim 19 wherein the wafer stage is mounted on another motion axis.

21. The method according to claim 19 wherein the monitoring step further comprising a first sensor connected to the first differential pump line wherein the sensor is mounted outside the process module.

22. The method according to claim 19 further comprising draining leaked first fluid from the process module using a drain mounted outside the process module.

23. The method according to claim 19 further comprising:
injecting a second fluid to the rotational wafer stage, the second fluid line is covered by the dynamic seal at a second connection point to the rotational wafer stage;
monitoring for a presence of the second fluid within the dynamic seal using a second leak sensor; and
differentially pumping the presence of the second fluid from the dynamic seal through a second differential pump line based on the monitoring step of the presence of the second fluid.

24. The method according to claim 23 wherein said second leak sensor is mounted outside the process module.

25. The method according to claim 23 further comprising a vacuum gauge operatively connected to the second differential pump line, said vacuum gauge is mounted outside the process module.

26. The method according to claim 19 further comprising monitoring a first rate of pressure rise in the first differential pump line; projecting a first time to reach a first pre-determined maximum differential pressure; and generating a first alert as to when the dynamic seal will need to be replaced.

27. The method according to claim 26 further comprising monitoring a second rate of pressure rise in the second differential pump line; projecting a second time to reach a second pre-determined maximum differential pressure; and generating a second alert as to when the dynamic seal will need to be replaced.
